(19) United States
(12) Patent Application Publication
(10) Pub. No.: US 2026/0282272 A1
(43) Pub. Date: Sep. 17, 2026

(54) SCALED-CAPACITY EMBODIMENT OF A MATERIAL-DRIVEN THERMAL MANAGEMENT ARCHITECTURE

(71) Applicant: FAIZAN AHMED, SAN JOSE, CA (US)

(72) Inventor: FAIZAN AHMED, SAN JOSE, CA (US)

(21) Appl. No.: 19/446,691

(22) Filed: Jan. 12, 2026

Related U.S. Application Data
(60) Provisional application No. 63/770,866, filed on Mar. 12, 2025.
(60) Provisional application No. 63/770,791, filed on Mar. 12, 2025.
(60) Provisional application No. 63/770,782, filed on Mar. 12, 2025.
(60) Provisional application No. 63/770,585, filed on Mar. 12, 2025.
(60) Provisional application No. 63/770,591, filed on Mar. 12, 2025.
(60) Provisional application No. 63/770,592, filed on Mar. 12, 2025.
(60) Provisional application No. 63/770,785, filed on Mar. 12, 2025.

(51) Int. Cl. H05K 7/20; H05K 5/00

(52) U.S. Cl. CPC H05K 7/20154; H05K 5/0018; H05K 7/20145; H05K 7/20209; H05K 7/20481; H05K 7/20945

(57) ABSTRACT

A portable temperature controlled enclosure comprises an external enclosure defining a thermally managed payload volume, an internal aluminum cooling chamber disposed within the external enclosure and configured to receive a payload, a cooling loop thermally coupled to the internal aluminum cooling chamber at a cooling interface region, and a fan assembly arranged to drive airflow across a heat exchange region of the cooling loop to reject heat to ambient. The internal aluminum cooling chamber includes a non-uniform geometry comprising geometric variations disposed along bottom portions and side portions of the internal aluminum cooling chamber. The non-uniform geometry is configured to establish differential cooling zones in which a first region of the internal aluminum cooling chamber cools at a first rate and a second region of the internal aluminum cooling chamber cools at a second rate during a cooldown interval.

### CLAIM OF PRIORITY

This application claims priority to U.S. Provisional Patent Application No. 63/770,866, filed on Mar. 12, 2025. This provisional patent application is hereby incorporated by reference.

This application claims priority to U.S. Provisional Patent Application No. 63/770,791, filed on Mar. 12, 2025. This provisional patent application is hereby incorporated by reference.

This patent application claims priority to U.S. Provisional Patent Application No. 63/770,782, filed on Mar. 12, 2025. This United States Provisional Patent Application is hereby incorporated by reference in its entirety.

This application claims priority to U.S. Provisional Patent Application No. 63/770,585, filed on Mar. 12, 2025. This United States Provisional Patent Application is hereby incorporated by reference in its entirety.

This patent application claims priority to U.S. Provisional Patent Application No. 63/770,591, filed on Mar. 12, 2025. This United States Provisional Patent Application is hereby incorporated by reference in its entirety.

This patent application claims priority to U.S. Provisional Patent Application No. 63/770,592, filed on Mar. 12, 2025. This United States Provisional Patent Application is hereby incorporated by reference in its entirety.

This application claims priority to U.S. Provisional Patent Application No. 63/770,785 filed on Mar. 12, 2025. U.S. Provisional Patent Application No. 63/770,785 is incorporated by reference in its entirety.

### BACKGROUND

### Field of the Invention

The present invention relates generally to portable temperature-controlled storage systems, and more particularly to a scaled-capacity embodiment of a material-driven thermal management architecture.

### BACKGROUND

Temperature sensitive payloads, including biological specimens, pharmaceuticals, diagnostic reagents, and certain medical devices, often require storage and transport within narrow temperature bands and within defined transient limits during pull down, door open events, and ambient temperature excursions. Many portable solutions either use vapor compression hardware that is difficult to miniaturize for low noise and low power operation, or use passive cold sources that are constrained by finite stored cooling capacity and limited controllability. Battery powered operation further constrains achievable cooling capacity, heat rejection, duty cycle, and run time, particularly when the system must operate autonomously for extended periods.

Passive approaches based on ice packs or thermal control materials generally provide limited closed loop temperature regulation and can exhibit temperature drift as stored cooling capacity is depleted or as the thermal control material transitions through a temperature range. These approaches may also respond poorly to variable ambient conditions, frequent access events, and variable payload thermal loads, and may not maintain a consistent internal setpoint without active control of heat extraction and heat rejection.

Existing portable temperature controlled enclosures can also suffer from inefficient heat transfer between cooling elements and the payload chamber, including high interfacial thermal resistance, limited effective contact area, and non uniform conduction paths through chamber walls. Such limitations can produce spatial temperature gradients within the payload volume and inconsistent cooldown behavior, particularly in compact architectures where internal volume, airflow pathways, and component placement are tightly constrained. These thermal non uniformities can be exacerbated as system capacity increases, because scaling the payload volume can increase conduction path lengths and thermal mass while also increasing the difficulty of maintaining uniform heat flux distribution across chamber surfaces.

### BRIEF DESCRIPTION OF THE INVENTION

In one aspect, a portable temperature controlled enclosure comprises an external enclosure defining a thermally managed payload volume, an internal aluminum cooling chamber disposed within the external enclosure and configured to receive a payload, a cooling loop thermally coupled to the internal aluminum cooling chamber at a cooling interface region, and a fan assembly arranged to drive airflow across a heat exchange region of the cooling loop to reject heat to ambient. The internal aluminum cooling chamber includes a non-uniform geometry comprising geometric variations disposed along bottom portions and side portions of the internal aluminum cooling chamber. The non-uniform geometry is configured to establish differential cooling zones in which a first region of the internal aluminum cooling chamber cools at a first rate and a second region of the internal aluminum cooling chamber cools at a second rate during a cooldown interval.

### BRIEF DESCRIPTION OF THE DRAWINGS

FIG. 1 is a top view of example embodiment of a portable temperature-controlled enclosure, according to some embodiments.

FIGS. 2 and 3 are isometric views of example embodiment of a portable temperature-controlled enclosure, according to some embodiments.

FIG. 4 is a front view of example embodiment of a portable temperature-controlled enclosure, according to some embodiments.

FIG. 5 is a side view of example embodiment of a portable temperature-controlled enclosure, according to some embodiments.

FIG. 6-9 illustrate various example views of an aluminum cooling chamber portable unit, according to some embodiments.

FIG. 6 illustrates a top-view of aluminum cooling chamber portable unit, according to some embodiments.

FIG. 7 illustrates an isometric-view of aluminum cooling chamber portable unit, according to some embodiments.

FIG. 8 illustrates a rear-view of aluminum cooling chamber portable unit, according to some embodiments.

FIG. 9 illustrates a side-view of aluminum cooling chamber portable unit, according to some embodiments.

FIG. 10 is a block diagram of a sample computing environment that can be utilized to implement various embodiments.

FIG. 11 illustrates a logical view of a portable temperature-controlled enclosure, according to some embodiments.

FIG. 12 illustrates an isometric view of a portable temperature controlled enclosure, according to some embodiments.

FIG. 13 illustrates an isometric view of a portable temperature controlled enclosure in an open, top access configuration, according to some embodiments.

FIG. 14 illustrates a top view of the portable temperature controlled enclosure, according to some embodiments.

FIG. 15 illustrates a front view of the portable temperature controlled enclosure, according to some embodiments.

FIG. 16 illustrates a side view of the portable temperature controlled enclosure, according to some embodiments.

FIG. 17 illustrates a higher capacity embodiment of a portable temperature controlled enclosure and an associated internal aluminum cooling chamber, according to some embodiments.

The Figures described above are a representative set and are not an exhaustive with respect to embodying the invention.

### DESCRIPTION

Disclosed are a system, method, and article of manufacture for an scaled-capacity embodiment of a material-driven thermal management architecture. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown. Appendix A includes additional information for implementing various embodiments.

### Definitions

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Thermal control material (TCM) is a substance with a high heat of fusion which, melting and solidifying at a certain temperature, is capable of storing and releasing large amounts of energy. Heat is absorbed or released when the material changes from solid to liquid and vice versa. Example TCM materials can include, inter alia: organic (paraffin and nonparaffin), inorganic (salt hydrates and metallic alloys), and eutectic (mixture of two or more TCM components: organic, inorganic, and both).

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

Thermal control material (TCM) is a substance capable of storing and releasing thermal energy to regulate temperature. It is noted that TCM can include thermal control material s (TCM) such as paraffins, salt hydrates, and eutectic mixtures, thermal mass materials such as water or glycol solutions, and other heat storage media. TCM can include: Thermal control material s (TCM) that store energy through phase transitions (e.g., paraffins, salt hydrates, eutectic mixtures); Sensible heat storage materials that store energy through temperature change (e.g., water, glycol solutions, mineral oils, molten salts); Solid thermal mass materials providing thermal inertia (e.g., concrete, ceramic, stone, sand); Metallic thermal buffers with high conductivity (e.g., aluminum heat sinks, copper spreaders, graphite plates, metal foam); and Composite thermal materials combining multiple thermal management functions (e.g., metal matrix composites, polymer-TCM encapsulations, graphene-enhanced compounds).

### Example Smart Refrigerator Exterior Views

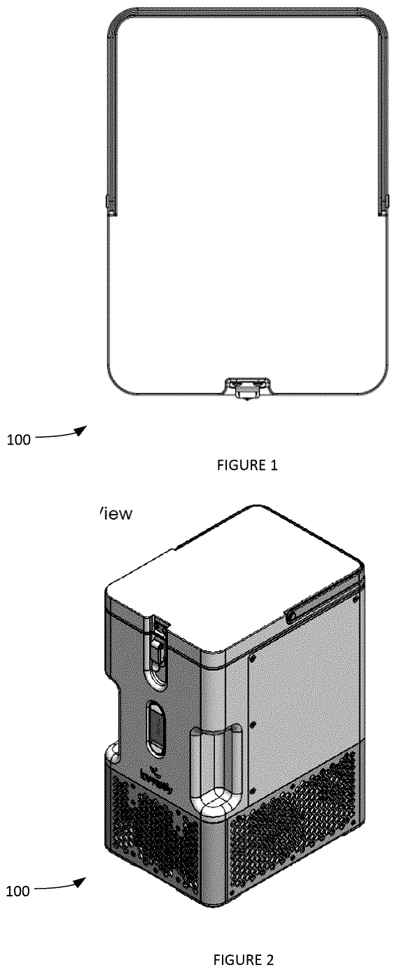

FIGS. 1-5 provide series of views of an example embodiment of a portable temperature-controlled enclosure 100, according to some embodiments. The series of views includes a set of orthographic views (e.g. top, front, side, and isometric) of the portable temperature-controlled enclosure according to one embodiment. The example embodiment of a portable temperature-controlled enclosure 100 can be a top loaded system. Portable temperature-controlled enclosure 100 can include an optimized solid-state cooling system (e.g. see infra). Portable temperature-controlled enclosure 100 provides a portable temperature-controlled enclosure utilizing an innovative solid-state cooling system with optimized thermal management. Portable temperature-controlled enclosure 100 combines advanced thermoelectric cooling technology with control systems to achieve superior temperature stability and extended battery operation.

Portable temperature-controlled enclosure 100 comprises several key components working in concert: a precision-engineered payload chamber for storing temperature-sensitive materials, an optimized thermoelectric cooling system with angular mounting configuration, an integrated TCM chamber for thermal buffering, and a heat dissipation system including honeycomb ventilation. These components are managed by advanced monitoring and control systems, all supported by extended battery-powered operation capability.

The top-loading portable temperature-controlled enclosure 100 represents a breakthrough in portable refrigeration technology, utilizing solid-state cooling principles to maintain precise temperature control. The top-loading portable temperature-controlled enclosure 100 distinguishes itself through the complete elimination of traditional cooling infrastructure components such as compressors, refrigerant gases, cooling coils, ice packs, or gel packs.

Example physical specifications of the top-loading portable temperature-controlled enclosure 100 are now discussed. The top-loading portable temperature-controlled enclosure 100 payload capacity, by way of example, can be a one (1) liter. The top-loading portable temperature-controlled enclosure 100 can include a top-loading design with example dimensions of 107.78 mm×119.92 mm×166.84 mm.

Access to the top-loading portable temperature-controlled enclosure 100 can be via a top-mounted lid providing full access to internal chamber. Construction of The top-loading portable temperature-controlled enclosure 100 can include precision-engineered aluminum chamber with integrated cooling system.

An example Core Cooling Technology of the top-loading portable temperature-controlled enclosure 100 is now discussed. The top-loading portable temperature-controlled enclosure 100 employs an advanced solid-state cooling mechanism based on semiconductor physics. As a cooling principle, the top-loading portable temperature-controlled enclosure 100 utilizes an electron mobility differential between semiconductor materials. By way of operation, the top-loading portable temperature-controlled enclosure 100 uses an electric current passage through dual-semiconductor junction.

The thermal energy absorption during electron transition between materials is implemented to optimizes cooling efficiency. The top-loading portable temperature-controlled enclosure 100 can achieve target temperature (2° C.) within 2-hour initialization period. The top-loading portable temperature-controlled enclosure 100 implements temperature maintenance to maintain 2-8° C. range for 72 hours without external power.

An example Thermal Management System of the internal payload chamber incorporates a thermal management design. As seen below, the top-loading portable temperature-controlled enclosure 100 includes a chamber construction that includes payload 104. Here, the material composition can include a specialized heat-absorbing material combined with aluminum. The top-loading portable temperature-controlled enclosure 100 utilizes thermal spreading via an engineered aluminum structure for optimal temperature distribution. The top-loading portable temperature-controlled enclosure 100 performs heat absorption via a material matrix for thermal energy management.

The top-loading portable temperature-controlled enclosure 100 provides dynamic temperature control. Primary cooling is performed via a solid-state semiconductor chip (e.g. discussed infra). Supplementary cooling can be performed via a thermal mass buffer system. Hybrid operation between thermal mass and active cooling Response system can be used for temperature maintenance. Automated cooling bursts for temperature deviation compensation can be performed.

The top-loading portable temperature-controlled enclosure 100 can include a power and environmental adaptation power system 1102. The top-loading portable temperature-controlled enclosure 100 includes an input compatibility, by way of example of a Universal AC power (110V/220V) and an integrated charging system. Battery operation can be for 72-hour autonomous operation capability.

Optimized power consumption during steady-state operation can be obtained using bi-directional temperature control capability. For example, in a winter mode operation, the top-loading portable temperature-controlled enclosure 100 functions in extreme cold environments (−20° C. to −30° C.). Thermal management systems 1104 of the top-loading portable temperature-controlled enclosure 100 can maintains 2-8° C. in both hot and cold ambient conditions. An example environmental range enables The top-loading portable temperature-controlled enclosure 100 to be functional across extreme temperature variations.

The top-loading portable temperature-controlled enclosure 100 includes a monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording. The top-loading portable temperature-controlled enclosure 100 can also perform automated cloud data synchronization.

The top-loading portable temperature-controlled enclosure 100 includes an Operation and Performance Temperature Performance module that manages an initial cooldown (e.g. 2 hours to reach target temperature with a temperature range: 2-8° C. maintenance and operation duration of 72 hours on battery power).

A thermal interface material utilizes a high thermal conductivity compound with controlled thickness application and full surface coverage verification. Mounting pressure can be maintained at 30-40 PSI through a spring-loaded mechanism, ensuring even pressure distribution across the chip surface and compensation for thermal expansion and contraction in some example embodiments.

The top-loading configuration represents a significant advancement in portable temperature-controlled storage, combining innovative solid-state cooling technology with thermal management and monitoring systems. The design achieves exceptional efficiency and reliability while maintaining precise temperature control across varied environmental conditions.

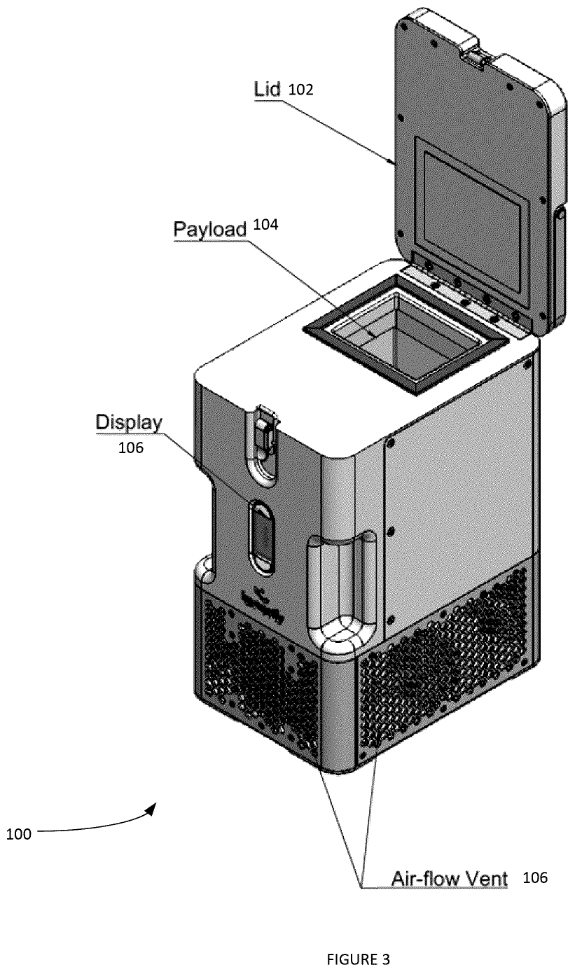

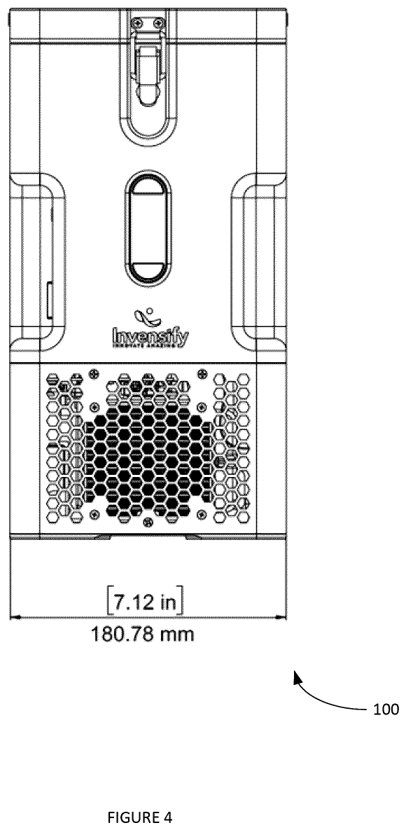

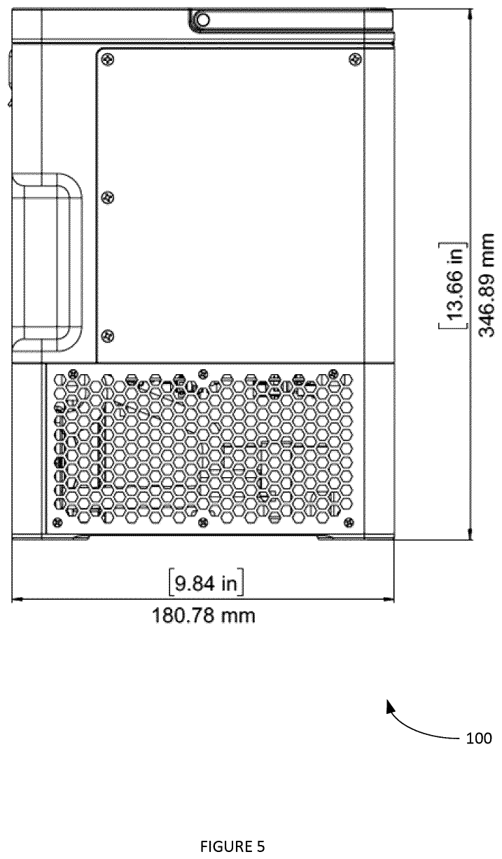

More specifically, FIG. 1 is a top view of example embodiment of a portable temperature-controlled enclosure 100, according to some embodiments. FIGS. 2 and 3 are isometric views of example embodiment of a portable temperature-controlled enclosure 100, according to some embodiments. FIG. 4 is a front view of example embodiment of a portable temperature-controlled enclosure 100, according to some embodiments. FIG. 5 is a side view of example embodiment of a portable temperature-controlled enclosure 100, according to some embodiments.

In one embodiments, portable temperature-controlled enclosure 100 can have a top-loading configuration with example payload dimensions: 3.2″×4.1″×5.5″. An example top opening capacity can be one (1) liter. Overall dimensions, by way of example, can be 107.78 mm×119.92 mm×166.84 mm. Portable temperature-controlled enclosure 100 provides a top access lid for payload (e.g. medications, etc.) insertion.

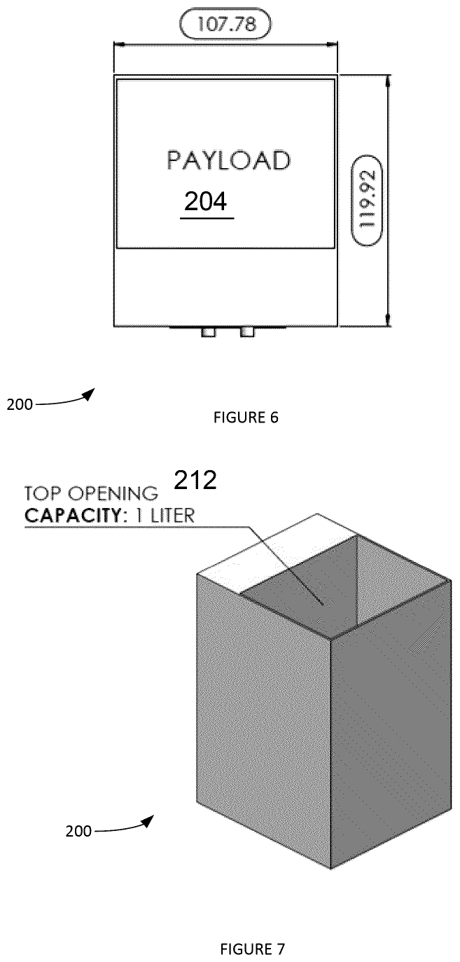

FIG. 6-9 illustrate various example views of an aluminum cooling chamber portable unit 200, according to some embodiments. Aluminum cooling chamber portable unit 200 can be the internal cooling/heating system of portable temperature-controlled enclosure 100.

Aluminum cooling chamber portable unit 200 of portable temperature-controlled enclosure 100 comprises a thermoelectric cooling mechanism wherein electrical power is transmitted through a strategically positioned semiconductor chip 202 mounted at a calculated angular orientation relative to the aluminum payload chamber 204. The semiconductor chip 202 incorporates a material combination wherein electrons traverse between different semiconductor elements, creating an energy absorption effect at the material junction interfaces. This energy absorption phenomenon, occurring at the precise locations where the material composition transitions, facilitates the cooling process through electron mobility differentials between the semiconductor materials.

The thermal management system utilizes direct thermal coupling between the semiconductor chip 202 and an aluminum payload chamber 204, whereby the energy absorption at the material junctions actively extracts heat from the payload area through the aluminum wall interface. The extracted thermal energy is subsequently transferred to a closed-loop cooling system 206 comprising fluid-carrying pipes 208 directly coupled to the posterior surface of the semiconductor chip (e.g. can include a heat sink system). The cooling loop 206 employs either water or antifreeze as the working fluid, circulating through an engineered pipe network via an integrated pump mechanism.

The system's thermal circuit can be completed through a fan-assisted heat exchanger configuration 214, wherein the heated working fluid from the cooling loop 206 is actively cooled before being recirculated through the system. The angular mounting of the semiconductor chip, deliberately oriented at a calculated angle rather than perpendicular to the payload chamber, achieves enhanced cooling distribution by optimizing the radius of coolness spread and increasing the effective surface area coverage. This angular configuration demonstrably improves the speed and uniformity of temperature distribution compared to traditional perpendicular mounting arrangements.

The thermal control system can operate in a dual-power configuration, initially utilizing wall power for the cooldown phase until the target temperature (typically 2° C.) is achieved, at which point the system transitions to battery power through a lithium polymer battery assembly capable of maintaining temperature control for 72 hours of autonomous operation. The internal configuration includes various top-loading variants (e.g. via top opening 212, etc.) while maintaining identical operational principles, with the semiconductor chip positioning optimized for each configuration to maximize cooling efficiency through enhanced radial distribution patterns.

The angular orientation of the semiconductor chip 202 relative to the payload chamber wall facilitates superior thermal spreading characteristics. The cooling effect disperses in a radial pattern rather than traditional linear distribution, resulting in more efficient coverage of the payload surface area and accelerated temperature equalization throughout the chamber. This geometric optimization of the semiconductor chip 202 placement enables the system to achieve more comprehensive thermal coverage compared to conventional perpendicular mounting configurations, as the angular positioning creates an expanded radius of cooling influence that enhances the overall heat absorption efficiency of the system.

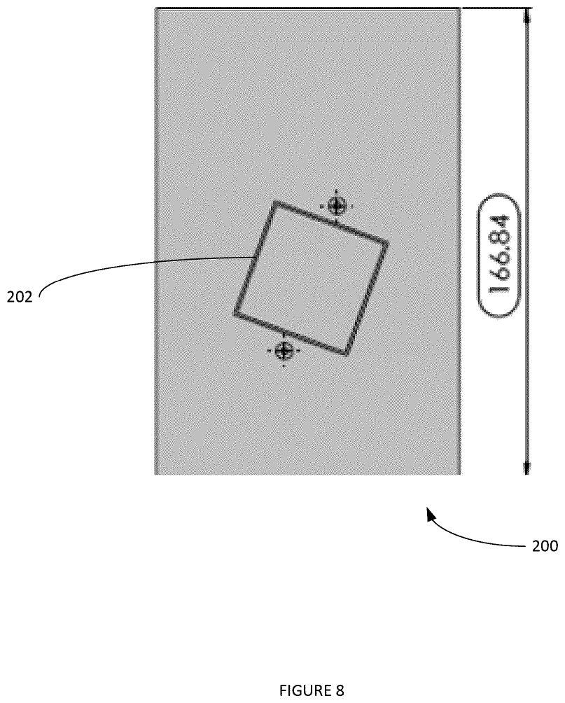

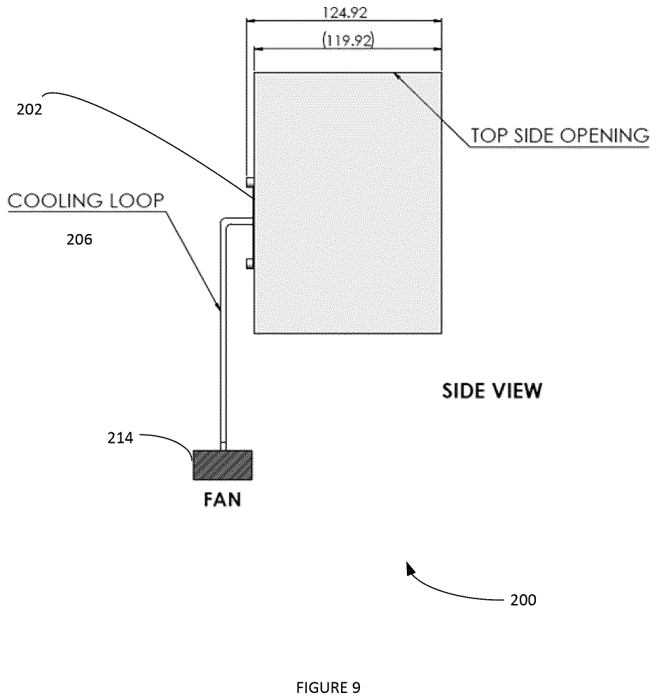

More specifically, FIG. 6 illustrates a top-view of aluminum cooling chamber portable unit 200, according to some embodiments. FIG. 7 illustrates a isometric-view of aluminum cooling chamber portable unit 200, according to some embodiments. FIG. 8 illustrates a rear-view of aluminum cooling chamber portable unit 200, according to some embodiments. FIG. 9 illustrates a side-view of aluminum cooling chamber portable unit 200, according to some embodiments.

### Example Computer Architecture and Systems

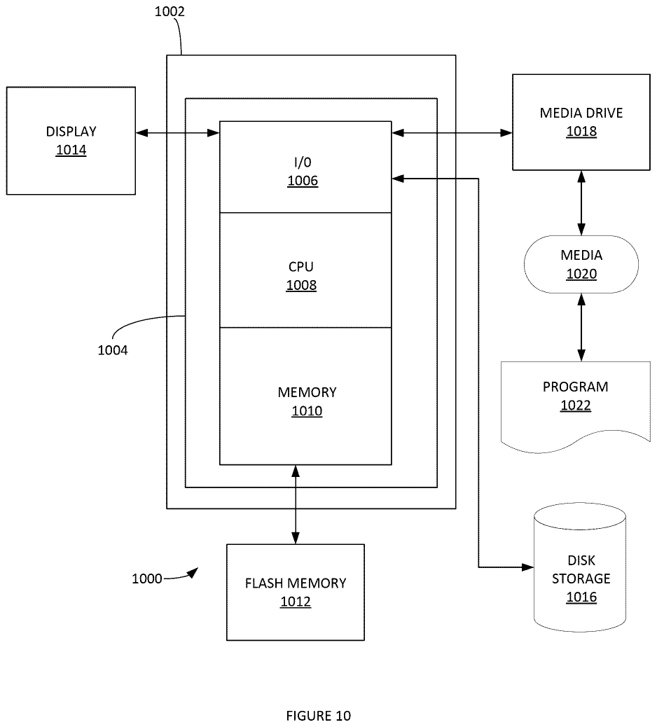

FIG. 10 depicts an exemplary computing system 1000 that can be configured to perform any one of the processes provided herein. In this context, computing system 1000 may include, for example, a processor, memory, storage, and I/O devices (e.g., monitor, keyboard, disk drive, Internet connection, etc.). However, computing system 1000 may include circuitry or other specialized hardware for carrying out some or all aspects of the processes. In some operational settings, computing system 1000 may be configured as a system that includes one or more units, each of which is configured to carry out some aspects of the processes either in software, hardware, or some combination thereof.

FIG. 10 depicts computing system 1000 with a number of components that may be used to perform any of the processes described herein. The main system 1002 includes a motherboard 1004 having an I/O section 1006, one or more central processing units (CPU) 1008, and a memory section 1010, which may have a flash memory card 1012 related to it. The I/O section 1006 can be connected to a display 1014, a keyboard and/or other user input (not shown), a disk storage unit 1016, and a media drive unit 1018. The media drive unit 1018 can read/write a computer-readable medium 1020, which can contain programs 1022 and/or data. Computing system 1000 can include a web browser. Moreover, it is noted that computing system 1000 can be configured to include additional systems in order to fulfill various functionalities. Computing system 1000 can communicate with other computing devices based on various computer communication protocols such a Wi-Fi, Bluetooth® (and/or other standards for exchanging data over short distances includes those using short-wavelength radio transmissions), USB, Ethernet, cellular, an ultrasonic local area communication protocol, etc.

Thermo-electric cooler pump can be managed by a computing system in the portable smart refrigerator. The computing system can be coupled with an exterior display. Exterior display can display various parameters (e.g. temperature, batter power, etc.) of the portable smart refrigerator. Computing system can also be coupled with various other systems such as, inter alia: temperature sensors, digital clocks, Wi-Fi systems, etc.

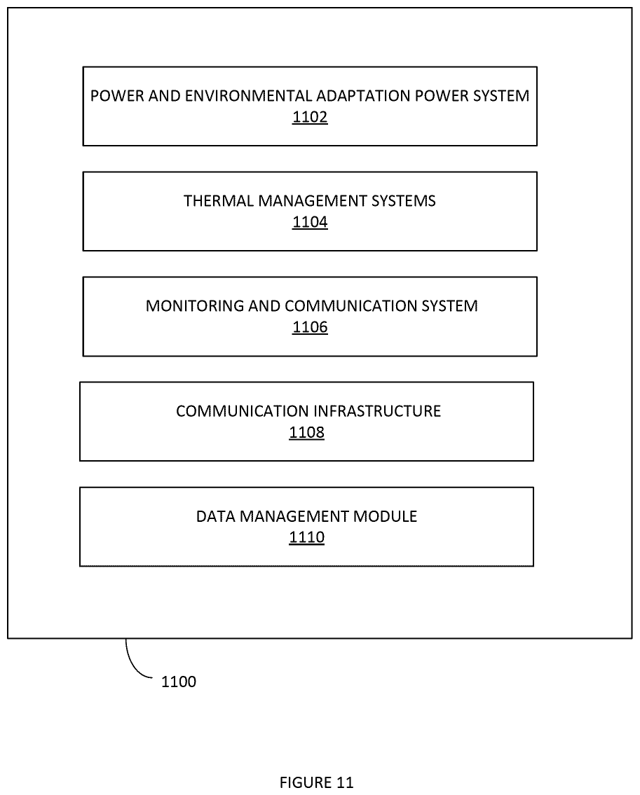

FIG. 11 illustrates a logical view 1100 of a portable temperature-controlled enclosure, according to some embodiments. Power and environmental adaptation power system 1102. The top-loading portable temperature-controlled enclosure 100 includes an input compatibility, by way of example of a Universal AC power (110V/220V) and an integrated charging system. Thermal management systems 1104 manage the temperature of top-loading portable temperature-controlled enclosure 100. Thermal management systems 110 of the top-loading portable temperature-controlled enclosure 100 can maintain 2-8° C. in both hot and cold ambient conditions. Monitoring and communication system 1106 for temperature monitoring. Real-time temperature tracking is implemented across continuous internal temperature measurement. The top-loading portable temperature-controlled enclosure 100 includes a digital display for current temperature indication. The top-loading portable temperature-controlled enclosure 100 includes an alert system for temperature deviations. The top-loading portable temperature-controlled enclosure 100 includes a communication infrastructure 1108 that can include an integrated LTE module with SIM card and/or GPS location tracking capability. The top-loading portable temperature-controlled enclosure 100 can perform data transmission intervals (e.g. at 4-5 minutes. The top-loading portable temperature-controlled enclosure 100 also includes cloud connectivity for remote monitoring. A backup SD card storage system can be included for offline data logging. The top-loading portable temperature-controlled enclosure 100 includes a Data Management module 1110 for continuous temperature logging and location tracking and recording.

Additional information on chip positioning is now discussed. The innovative cooling system centers around a precisely engineered 40 mm×40 mm semiconductor chip that represents a significant advancement in portable refrigeration technology. This chip, comprising multiple semiconductor junctions arranged in an optimized pattern, is mounted at a carefully calculated 20-degree angle relative to the payload chamber wall, deviating from traditional perpendicular mounting approaches. This specific angular orientation was chosen to maximize the cooling efficiency through enhanced radial distribution patterns.

The mounting configuration creates a thermal management system where the chip interfaces directly with the aluminum chamber wall for maximum thermal conductivity. This direct coupling is maintained by a spring-loaded mechanism that ensures a consistent 30-40 PSI mounting pressure, crucial for optimal heat transfer. The interface between the chip and wall utilizes a high thermal conductivity compound with carefully controlled thickness and verified full surface coverage.

The 20-degree mounting angle serves a critical purpose in the system's operation. Unlike conventional perpendicular mounting, which typically results in linear cooling distribution, this angular orientation creates an expanded radius of cooling influence. This radial distribution pattern enables more comprehensive coverage of the payload surface area and facilitates faster temperature equalization throughout the chamber. The result is a more efficient and effective cooling system that achieves superior thermal coverage compared to traditional mounting configurations.

In the top-loaded configuration, the chip is positioned lower, near the midsection of the wall, with the temperature sensor strategically placed inside the payload wall towards the bottom side. This positioning was specifically chosen to optimize the cooling effect in relation to the temperature sensor location. The entire setup demonstrates a carefully engineered approach to thermal management, where each component's position has been optimized for maximum efficiency.

The semiconductor chip's design and mounting create a cooling effect that disperses in a radial pattern rather than a traditional linear distribution. This radial dispersion is particularly effective because it provides more uniform coverage across the payload area. The angular mounting effectively increases the total area over which the cooling effect spreads, resulting in more efficient temperature control throughout the chamber. This innovative approach to chip mounting and cooling distribution represents a significant advancement in portable refrigeration technology, offering improved performance over conventional perpendicular mounting systems.

The system's overall design reflects a deep understanding of thermal dynamics and practical engineering considerations. By combining the precise 40 mm×40 mm chip dimensions with the 20-degree mounting angle and strategic positioning relative to temperature sensors, the system achieves optimal cooling performance while maintaining efficient use of space within the portable unit. The careful attention to mounting pressure, thermal compound application, and interface design ensures reliable and consistent performance, making this cooling system particularly well-suited for portable applications requiring precise temperature control.

### Scaled-Capacity Embodiment of a Material-Driven Thermal Management Architecture

In an example of scaled-capacity embodiment of a material-driven thermal management architecture, a 42-liter cooling system can be implemented as a scaled-capacity embodiment in which an external enclosure defines a thermally managed payload volume and supports an internal aluminum cooling chamber configured to receive and cool the payload. In an example configuration, the external enclosure can have overall dimensions of about 18.72 inches (475.37 mm) in width, about 22.21 inches (564.17 mm) in height, and about 15.22 inches (386.67 mm) in depth.

The internal aluminum cooling chamber can define a payload space having dimensions of about 13.82 inches by about 16.00 inches by about 11.60 inches, thereby supporting a nominal 42-liter capacity. The internal aluminum cooling chamber can be formed as a non-uniform geometry including one or more pocketed regions, recessed regions, stepped regions, contoured regions, and/or thickness variations disposed along bottom portions and side portions of the internal aluminum cooling chamber. In some embodiments, the non-uniform geometry is intentionally selected to modify conduction path lengths, local thermal mass distribution, and effective surface area, thereby controlling a transient cooling response of the internal aluminum cooling chamber during pull-down from an initial temperature toward a target temperature.

In some embodiments, the non-uniform geometry of the internal aluminum cooling chamber is determined using one or more mechanical and thermal calculations that relate chamber geometry to cooldown behavior and thermal distribution. By way of example, the mechanical and thermal calculations can include one or more analytical models, numerical simulations, and/or empirically tuned parameter sets that estimate or constrain one or more thermal coefficients (e.g., an effective thermal resistance between a cooling interface region and a distal chamber region, a thermal time constant associated with the internal aluminum cooling chamber, and/or an effective heat-transfer coefficient associated with a chamber wall region). Based on such calculations, the internal aluminum cooling chamber can be configured to establish differential cooling zones in which first regions of the internal aluminum cooling chamber cool at a first-rate and second regions of the internal aluminum cooling chamber cool at a second-rate. The differential cooling zones can reduce spatial temperature gradients across the internal aluminum cooling chamber and promote more uniform temperature distribution within the payload volume during a cooldown interval.

The internal aluminum cooling chamber can have overall plan dimensions of about 16.00 inches (406.4 mm) in width and about 15.47 inches (393.0 mm) in length, with the pocketed regions and contoured regions integrated into bottom and/or side sections. In some embodiments, the pocketed regions are positioned to accelerate cooldown in thermally lagging regions of the payload volume and/or to reduce localized overcooling near a cooling interface region. In some embodiments, the non-uniform geometry reduces an overall time-to-target-temperature for the payload volume relative to an otherwise comparable internal aluminum cooling chamber having a substantially uniform wall geometry, for example by shaping a heat-flux distribution across the chamber walls and by staging the cooldown of different chamber regions in a controlled manner.

The external enclosure can include a top-loading configuration with reinforced corner structures and one or more air-flow vents configured to support convective heat rejection. A digital display panel can be mounted on the external enclosure and can be electrically coupled to control electronics configured to operate the thermal management system. The thermal management system can include a cooling loop and a fan assembly positioned to drive airflow across a heat exchange region of the cooling loop, thereby rejecting heat to ambient. In some embodiments, the cooling loop is thermally coupled to the internal aluminum cooling chamber at one or more cooling interface regions, and the fan assembly is arranged to provide forced convection across a condenser or radiator portion of the cooling loop.

In some embodiments, the cooling loop and fan assembly are positioned relative to the non-uniform surfaces of the internal aluminum cooling chamber to achieve a target thermal response and/or to maintain temperature uniformity. For example, a cooling interface region can be located proximate to a bottom contour feature of the internal aluminum cooling chamber such that a first cooling zone is established near the cooling interface region and one or more additional cooling zones propagate alongside surfaces having pocketed or stepped geometry. In this manner, the 42-liter cooling system can scale beyond a simple dimensional increase by employing geometry-driven thermal control in the internal aluminum cooling chamber to improve cooldown performance and spatial thermal distribution.

In some embodiments, a cooling block is thermally coupled to the payload chamber and mounted in an angular orientation relative to the payload chamber. For example, the cooling block can be positioned diagonally such that a principal face of the cooling block is oriented at an angle of about 40 degrees to about 45 degrees relative to a reference plane of the payload chamber (e.g., a rear wall plane, a bottom plane, and/or a plane parallel to an opening rim). The angular orientation can be selected to increase an effective contact region between the cooling block and a target chamber wall region and to create a non symmetric heat flux distribution into the payload chamber.

A solid state cooling chip can be disposed in a thermal stack beneath the cooling block such that the cooling block conducts heat to and from an active face of the cooling chip. In some embodiments, the cooling block defines a primary heat spreading mass that distributes cooling capacity from the cooling chip across an extended region of the payload chamber. The cooling block can include one or more surfaces configured to mate with a chamber wall region and can further include a thermally conductive interface material between the cooling block and the chamber wall region to reduce interfacial thermal resistance.

The payload chamber can include a thermally conductive fin structure disposed within the payload volume to improve heat exchange between the payload volume and the chamber wall regions. In some embodiments, the fin structure comprises an aluminum plate having multiple fins and a hydrocarbon coating on at least the fin surfaces. The fin structure can be mechanically coupled to the payload chamber (e.g., welded to the payload chamber wall) to establish a low resistance conduction path from the chamber wall into the fin structure and to increase an internal convective and radiative exchange area within the payload volume. In some embodiments, a thermal control material (TCM) can be retained in thermal communication with the fin structure and or the chamber wall to buffer transient temperature variations and to maintain a target payload temperature range.

In some embodiments, the angularly mounted cooling block, the cooling chip, and the internal fin structure operate cooperatively with non-uniform chamber geometry features of the payload chamber (e.g., pocketed regions, recessed regions, stepped regions, contoured regions, and or thickness variations) to produce a controlled transient cooling response. For example, the angular placement of the cooling block can bias heat extraction toward a first zone of the payload chamber while the non-uniform chamber geometry and internal fin structure distribute cooling capacity toward second zones that would otherwise lag, thereby reducing spatial temperature gradients across the payload volume during pull down.

The foregoing angular mounting configuration is not limited to a particular attachment mechanism. The cooling block can be secured to the payload chamber using one or more fasteners, brackets, bonded joints, and or welded interfaces, provided that the cooling block remains in thermal communication with the cooling chip and with a selected chamber wall region. In an example embodiment, the cooling block is disposed near a rear portion of the payload chamber and mounted at about 40 degrees to about 45 degrees, while the cooling chip is positioned beneath the cooling block, and the hydrocarbon coated fin plate is coupled to the payload chamber within the payload volume to enhance heat exchange and temperature uniformity.

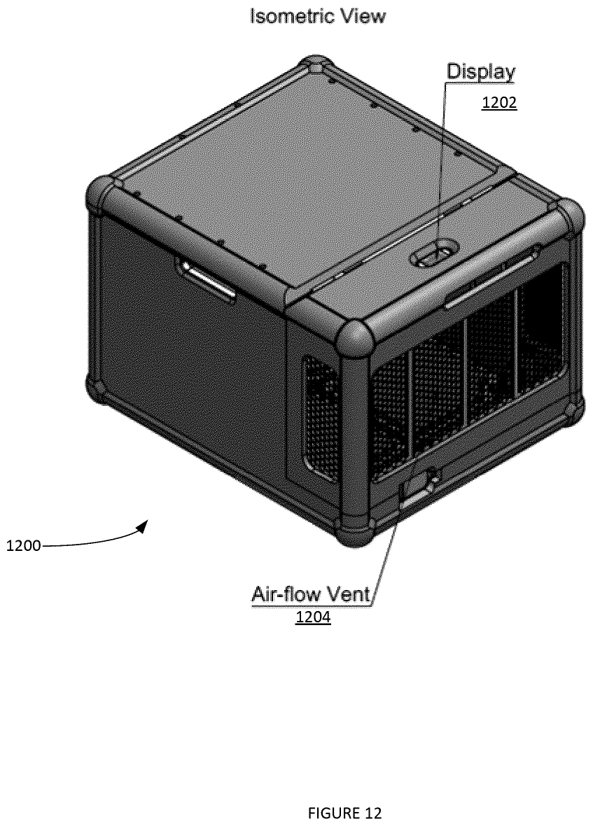

FIG. 12 illustrates an isometric view of a portable temperature controlled enclosure 1200, according to some embodiments. The portable temperature controlled enclosure 1200 includes an external housing having a generally rectangular form factor with reinforced corner structures and perimeter frame members. A display 1202 is disposed on an upper surface of the portable temperature controlled enclosure 1200 and can be configured to present operating information (e.g., measured internal temperature, a target temperature setpoint, an operating mode, battery status, and or alert conditions). An airflow vent 1204 is disposed on a side portion of the portable temperature controlled enclosure 1200. In some embodiments, the airflow vent 1204 includes a vent grille having a plurality of openings configured to support airflow through an internal equipment region that houses one or more thermal management components (e.g., a cooling loop, a condenser or radiator portion, and or a fan assembly) to reject heat to ambient.

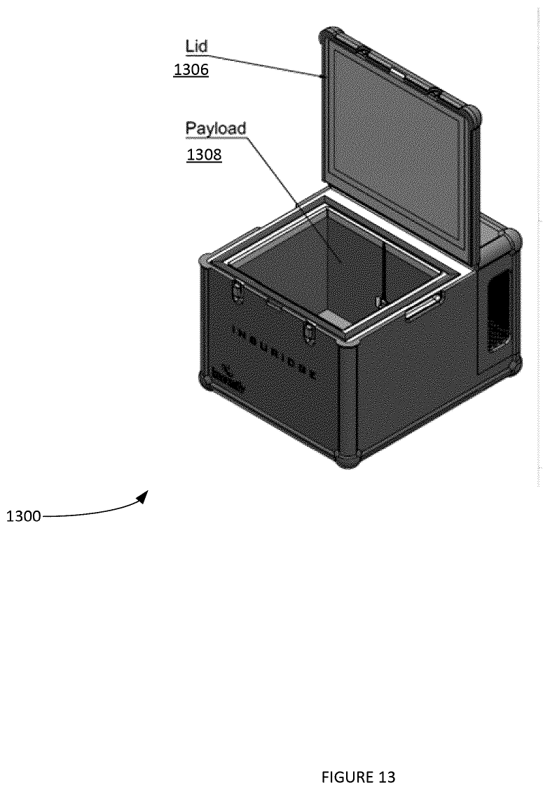

FIG. 13 illustrates an isometric view of a portable temperature controlled enclosure 1300 in an open, top access configuration, according to some embodiments. A lid 1306 is coupled to the external housing and is movable between a closed position and an open position about a hinge region disposed along a rear edge of a top opening. A payload cavity 1308 is accessible through the top opening when the lid 1306 is in the open position. In some embodiments, the payload cavity 1308 is defined by an inner liner and is recessed below an upper rim of the external housing. The upper rim can include a sealing surface configured to cooperate with the lid 1306 to reduce heat leakage and moisture ingress when the lid 1306 is closed. In some embodiments, one or more latch mechanisms are disposed on a front face of the portable temperature controlled enclosure 1300 to retain the lid 1306 in the closed position and to apply closure force sufficient to compress a gasket disposed along the rim.

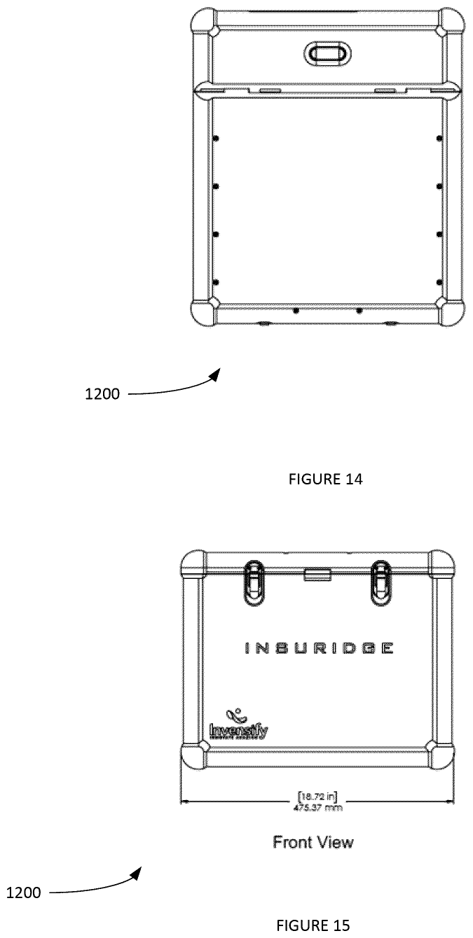

FIG. 14 illustrates a top view of the portable temperature controlled enclosure 1200, according to some embodiments. The top view depicts a top surface layout, a perimeter frame, and a handle opening disposed near a forward portion of the lid region. In some embodiments, the handle opening is configured for manual carrying and or for coupling to a handle component. The top view further depicts a plurality of fastener locations disposed along opposing side regions of the enclosure, which can correspond to attachment features for coupling outer panels, reinforcing members, and or internal brackets.

FIG. 15 illustrates a front view of the portable temperature controlled enclosure 1200, according to some embodiments. In the illustrated embodiment, latch mechanisms are disposed along an upper portion of the front face and are positioned to secure the lid to the enclosure rim. The front view further depicts the external frame members at the corners and along perimeter edges that provide impact resistance and structural rigidity. In some embodiments, the portable temperature controlled enclosure 1200 has an example external width of about 18.72 inches (475.37 mm).

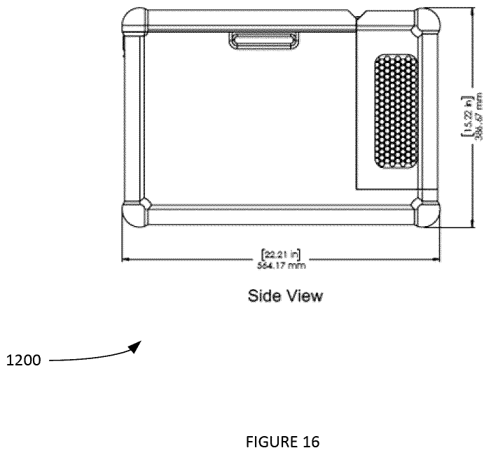

FIG. 16 illustrates a side view of the portable temperature controlled enclosure 1200, according to some embodiments. In the illustrated embodiment, a handle feature is disposed on a side face near an upper region of the enclosure to support manual transport. An airflow vent region is disposed on a side portion of the enclosure and can be positioned adjacent to an internal condenser or radiator and fan assembly region to support forced convection heat rejection. In some embodiments, the portable temperature controlled enclosure 1200 has example external dimensions of about 22.21 inches (564.17 mm) along a length dimension and about 15.22 inches (386.67 mm) along a height dimension.

FIG. 17 illustrates a higher capacity embodiment of a portable temperature controlled enclosure and an associated internal aluminum cooling chamber, according to some embodiments. The portable temperature controlled enclosure can include a lid, a payload region, an airflow vent, and a display, and can be represented using multiple views including isometric and orthographic views. In some embodiments, the internal aluminum cooling chamber defines a payload space having example dimensions of about 13.82 inches by about 16.00 inches by about 11.6 inches to provide a nominal capacity of about 42 liters. The internal aluminum cooling chamber can have example plan dimensions of about 16.00 inches (406.4 mm) by about 15.47 inches (393 mm) and can define a top side opening of about 15.63 inches (397 mm). In some embodiments, a cooling loop is positioned adjacent to the internal aluminum cooling chamber and a fan is positioned to drive airflow across a heat exchange region associated with the cooling loop, thereby rejecting heat to ambient and supporting temperature control of the payload space.

In some embodiments, the internal aluminum cooling chamber illustrated in FIGS. 12-17 is configured such that geometric non-uniformity is distributed asymmetrically relative to a centerline of the payload chamber. This asymmetry causes heat extraction and thermal propagation to occur preferentially along selected structural paths, thereby shaping a directional transient cooling profile within the payload volume.

In some embodiments, the pocketed, recessed, stepped, contoured, and thickness-varied regions of the internal aluminum cooling chamber collectively define a spatially graded thermal impedance map across the chamber walls. The thermal impedance map governs how heat is conducted from different regions of the payload chamber toward one or more cooling interface regions during pull-down and steady-state operation.

In some embodiments, the internal aluminum cooling chamber operates as a distributed thermal mass network in which localized increases in material thickness serve as thermal buffers while localized reductions in thickness act as accelerated heat transfer regions. The spatial arrangement of these regions can be selected to reduce peak thermal gradients within the payload volume during cooling transitions.

In some embodiments, the non-uniform chamber geometry is selected such that different regions of the payload chamber exhibit distinct thermal time constants. The distinct thermal time constants can be configured to stagger cooling behavior across the payload chamber, thereby reducing localized overcooling near the cooling interface while accelerating cooling of thermally lagging regions.

In some embodiments, the internal aluminum cooling chamber exhibits anisotropic effective thermal conductivity resulting from its non-uniform geometry and thickness variation. The anisotropic thermal behavior biases heat flow toward the cooling interface region while limiting lateral heat spreading into regions of the external enclosure that are less thermally coupled to the cooling loop.

In some embodiments, the hydrocarbon-coated fin structure illustrated in FIGS. 13 and 17 is configured to cooperate with the non-uniform chamber geometry to redistribute thermal energy within the payload volume. The hydrocarbon coating modifies surface interaction with internal air and payload packaging to enhance convective and radiative heat exchange while suppressing localized condensation and thermal hotspots.

In some embodiments, the fin structure is positioned relative to pocketed or contoured chamber wall regions such that heat extracted through the chamber wall is redistributed internally along preferred paths defined by fin orientation, fin spacing, and surface condition. This internal redistribution improves temperature uniformity without increasing cooling power.

In some embodiments, the angularly mounted cooling block illustrated in FIGS. 12 and 17 establishes a non-symmetric thermal coupling condition that intentionally biases heat extraction toward a first region of the payload chamber. The non-uniform chamber geometry and internal fin structure then propagate cooling capacity toward second regions of the payload chamber that would otherwise exhibit delayed cooldown.

In some embodiments, the cooling block functions as a primary heat spreading mass that distributes cooling capacity from the solid-state cooling chip across a chamber wall region having spatially varying thickness and geometry. This interaction causes cooling capacity to be redistributed by the chamber material itself prior to exchange with the payload volume.

In some embodiments, the internal aluminum cooling chamber and fin structure together form a passive thermal shaping system that moderates transient thermal disturbances caused by payload loading events, lid opening events, or ambient temperature changes, without requiring additional sensors or active control loops.

In some embodiments, the thermal management architecture illustrated in FIGS. 12-17 enables scaling of payload capacity while maintaining comparable cooldown performance by modifying chamber geometry and material distribution rather than proportionally increasing cooling power or airflow.

In some embodiments, the internal aluminum cooling chamber is configured to produce a repeatable thermal response that is substantially independent of payload composition. As a result, the cooling system can maintain consistent cooldown behavior across payloads having different thermal masses, packaging configurations, or loading patterns.

In some embodiments, the described combination of non-uniform chamber geometry, angular cooling block orientation, hydrocarbon-coated fin structure, and material-driven thermal distribution enables a reduction in overall energy consumption while achieving reduced time-to-target temperature and improved spatial temperature uniformity relative to systems employing uniform chamber walls and symmetric cooling interfaces.

### CONCLUSION

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

1. A portable temperature controlled enclosure, comprising:
an external enclosure defining a thermally managed payload volume;
an internal aluminum cooling chamber disposed within the external enclosure and configured to receive a payload;
a cooling loop thermally coupled to the internal aluminum cooling chamber at a cooling interface region, and
a fan assembly arranged to drive airflow across a heat exchange region of the cooling loop to reject heat to ambient,
wherein the internal aluminum cooling chamber includes a non-uniform geometry comprising geometric variations disposed along bottom portions and side portions of the internal aluminum cooling chamber, and
wherein the non-uniform geometry is configured to establish differential cooling zones in which a first region of the internal aluminum cooling chamber cools at a first rate and a second region of the internal aluminum cooling chamber cools at a second rate during a cooldown interval.

2. The portable temperature controlled enclosure of claim 1, wherein the geometric variations comprise one or more pocketed regions, recessed regions, stepped regions, contoured regions, thickness variations, or combinations thereof.

3. The portable temperature controlled enclosure of claim 2, wherein the non uniform geometry is configured to modify at least one of conduction path lengths through a wall of the internal aluminum cooling chamber, local thermal mass distribution of the internal aluminum cooling chamber, or effective surface area of the internal aluminum cooling chamber, thereby controlling a transient cooling response during pull down from an initial temperature toward a target temperature.

4. The portable temperature controlled enclosure of claim 3, wherein the non uniform geometry is selected using mechanical and thermal calculations that relate chamber geometry to cooldown behavior and thermal distribution.

5. The portable temperature controlled enclosure of claim 4, wherein the mechanical and thermal calculations estimate or constrain one or more thermal coefficients comprising an effective thermal resistance between the cooling interface region and a distal chamber region, a thermal time constant associated with the internal aluminum cooling chamber, an effective heat transfer coefficient associated with a chamber wall region, or combinations thereof.

6. The portable temperature controlled enclosure of claim 5, wherein the differential cooling zones are configured to reduce spatial temperature gradients across the internal aluminum cooling chamber and to promote a more uniform temperature distribution within the thermally managed payload volume during the cooldown interval.

7. The portable temperature controlled enclosure of claim 6, wherein the heat exchange region of the cooling loop comprises a condenser or radiator portion, and wherein the fan assembly is arranged to provide forced convection across the condenser or radiator portion.

8. The portable temperature controlled enclosure of claim 7, wherein the cooling interface region is disposed proximate to a bottom contour feature of the internal aluminum cooling chamber such that a first cooling zone is established proximate to the cooling interface region and one or more additional cooling zones propagate alongside a side portion having pocketed geometry, stepped geometry, or combinations thereof.

9. The portable temperature controlled enclosure of claim 8, further comprising a cooling block thermally coupled to a chamber wall region of the internal aluminum cooling chamber, wherein the cooling block is mounted in an angular orientation relative to a reference plane of the internal aluminum cooling chamber to bias heat extraction toward a first zone of the internal aluminum cooling chamber.

10. The portable temperature controlled enclosure of claim 9, further comprising a solid state cooling chip disposed in a thermal stack beneath the cooling block such that the cooling block conducts heat to and from an active face of the solid state cooling chip.

11. The portable temperature controlled enclosure of claim 9, wherein the cooling block includes a thermally conductive interface material between the cooling block and the chamber wall region to reduce interfacial thermal resistance.

12. The portable temperature controlled enclosure of claim 9, further comprising a thermally conductive fin structure disposed within the thermally managed payload volume, wherein the fin structure comprises an aluminum plate having multiple fins and a hydrocarbon coating disposed on at least fin surfaces, and wherein the fin structure is mechanically coupled to a wall of the internal aluminum cooling chamber to establish a low resistance conduction path from the wall into the fin structure.

13. The portable temperature controlled enclosure of claim 12, further comprising a thermal control material retained in thermal communication with the fin structure or with a wall of the internal aluminum cooling chamber to buffer transient temperature variations and to maintain a target payload temperature range.

14. The portable temperature controlled enclosure of claim 1, wherein the external enclosure comprises a top loading configuration having a lid movable between a closed position and an open position, a gasket disposed along an upper rim to reduce heat leakage when the lid is in the closed position, one or more latch mechanisms configured to retain the lid in the closed position and compress the gasket, an airflow vent disposed on a side portion of the external enclosure, a display disposed on an upper surface of the external enclosure, and control electronics electrically coupled to the display and configured to operate the cooling loop and the fan assembly.

15. The portable temperature controlled enclosure of claim 1, wherein the external enclosure has overall dimensions of about 18.72 inches (475.37 mm) in width, about 22.21 inches (564.17 mm) in height, and about 15.22 inches (386.67 mm) in depth, wherein the internal aluminum cooling chamber defines a payload space having dimensions of about 13.82 inches by about 16.00 inches by about 11.60 inches, wherein the internal aluminum cooling chamber has plan dimensions of about 16.00 inches (406.4 mm) in width and about 15.47 inches (393.0 mm) in length, and wherein a top side opening of the internal aluminum cooling chamber is about 15.63 inches (397 mm).

16. The portable temperature controlled enclosure of claim 9, wherein the cooling block is mounted diagonally such that the principal face of the cooling block is oriented at an angle of about 40 degrees to about 45 degrees relative to the reference plane of the internal aluminum cooling chamber.
